(19) United States
(12) Patent Application Publication
(10) Pub. No.: US 2003/0173999 A1
(43) Pub. Date: Sep. 18, 2003

(54) Activity detector circuit

(76) Inventors: Rien Gahlsdorf, Nashua, NH (US); Fouad Kiamilev, Hockessin, DE (US)

Correspondence Address: MORGAN & FINNEGAN, L.L.P., 345 Park Avenue, New York, NY, 10154-0053, US

(21) Appl. No.: 10/389,839

(22) Filed: Mar. 17, 2003

Related U.S. Application Data
(60) Provisional application No. 60/365,686, filed on Mar. 18, 2002.

(51) Int. Cl. H03K 5/153

(52) U.S. Cl. 327/77

(57) ABSTRACT

An activity detection system for use with a signal having a high value and a low value has a differential amplifier, a filter and a comparator configured to compare a signal to a threshold value and determine if the threshold value is above the signal, below the signal or in between the high and low values of the signal.

### CROSS REFERENCE TO RELATED APPLICATIONS

This application claims priority under 35 USC 119(e)(1) of U.S. Provisional Patent Application Serial No. 60/365,686 filed Mar. 18, 2002.

### FIELD OF THE INVENTION

The present invention relates generally to electronic detection devices, and relates more particularly to activity detector circuits.

### BACKGROUND

Activity detection systems can be used to monitor the voltage or current levels of a particular system. However, often times these activity detection systems are simple comparators that compare the voltage or current level against a predetermined threshold level that cannot be easily changed.

The output of these activity detection systems of the prior art are also simplistic, often times the output is a single bit, with a “1” representing active and a “0” representing inactive.

### SUMMARY OF THE INVENTION

We have devised an invention that allows creation of an activity detection system that can monitor activity, ascertain high and low levels of a signal, and determine if a signal has been on or off for an extended period of time. This flexibility allows a single activity detection system constructed according to the invention to be used for any one or more of a number of applications that previously may have had to be done discretely. The system and its various applications are described in detail below.

The advantages and features described herein are a few of the many advantages and features available from representative embodiments and are presented only to assist in understanding the invention. It should be understood that they are not to be considered limitations on the invention as defined by the claims, or limitations on equivalents to the claims. For instance, some of these advantages are mutually contradictory, in that they cannot be simultaneously present in a single embodiment. Similarly, some advantages are applicable to one aspect of the invention, and inapplicable to others. Thus, this summary of features and advantages should not be considered dispositive in determining equivalence. Additional features and advantages of the invention will become apparent in the following description, from the drawings, and from the claims.

### BRIEF DESCRIPTION OF THE DRAWINGS

FIG. 1 is a block diagram of an activity detection system according to the present invention;

FIG. 2 is an example graph of one aspect of the operation of an activity detection system according to the present invention;

FIG. 3 is a graph of a second aspect of the operation of the activity detection system according to the present invention;

FIG. 4 is a graph of a third aspect of the operation of the activity detection system according to the present invention; and

FIG. 5 is a graph of a fourth aspect of the operation of the activity detection system according to the present invention.

### DETAILED DESCRIPTION

In accordance with the invention several operations can be performed by a common activity detector system. These operations include detecting an inactive signal, find the high and low values of a signal, detecting a signal that has been low for an extended period of time, detecting a signal that has been on for an extended period of time, and detecting the DC averages of a signal using multiple thresholds. The activity detector system according to the present invention is able to perform all those operations. Moreover by adding a control system, for example a programmed processor, microprocessor or other control circuitry, the activity detector system according to the present invention is able to perform all the operations automatically, without reprogramming from a user.

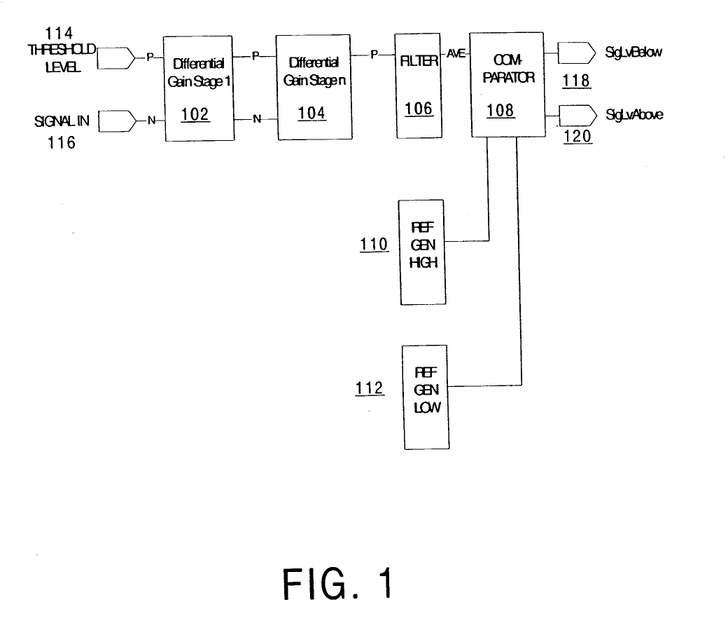

FIG. 1 is a block diagram of the activity detection system according to the present invention. The system in this example is built with two differential gain stages 102 and 104 that outputs voltage levels according to the differences between the voltage level of the input signal 116 and the threshold level 114. More differential gain stages may be necessary depending on the application of the device. A filter 106 is connected to the output of the differential gain stages to obtain a filtered average signal level. In alternative variants it is potentially useful to dynamically change the values of the capacitor used in the filter so that it can act similarly with a high frequency input signal. For example, the capacitance would be decreased in case of a high frequency input signal and increased in case of a low frequency input signal. A comparator 108 compares the signal filter voltage level with two reference voltages, high reference 110 and low reference 112, and generates two outputs to indicate if the signal filter voltage signal is above or below the reference voltages. These two outputs are signal level below 118 and signal level above 120.

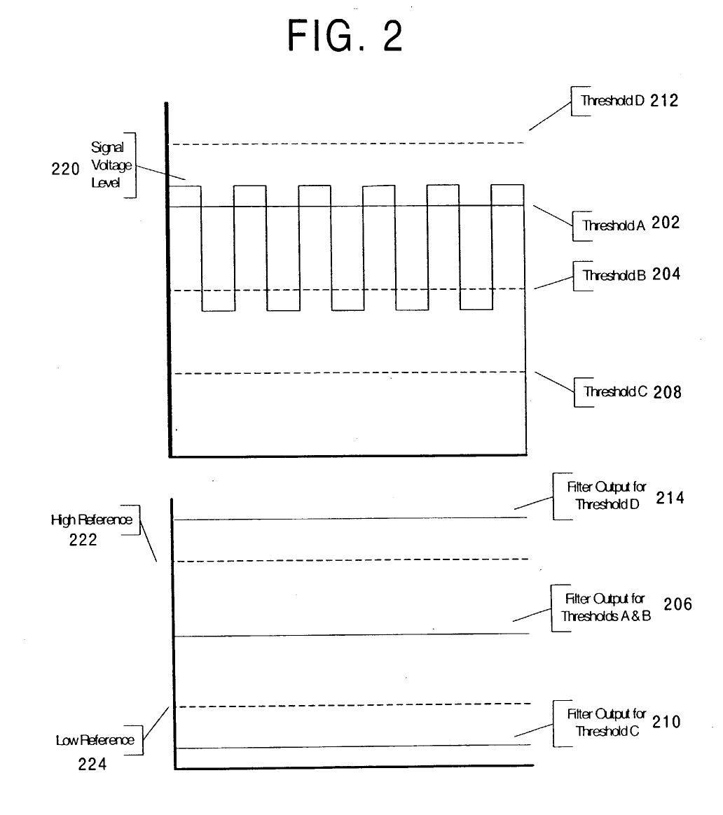

Some individual operations of the activity detector system are depicted in FIG. 2. FIG. 2 is a graph of one operation by the activity detection system according to the present invention. A signal voltage level 220 is applied at the input. The threshold level at the other end of the differential gain stage 102 may be threshold “A” 202 or threshold “B” 204, wherein the threshold level is within the swing range of the signal voltage level 220. When the threshold level is within the swing range, the differential gain stages 102 and 104 will amplify the signal voltage level 220 to full digital levels. The filter 106 then finds the average of the signal voltage level 220. Because the signal voltage level 220 has been amplified to full digital levels, the output voltage level of the filter 106 will be the midpoint of the digital range. Therefore, the filter output 206 for both threshold “A” 202 and threshold “B” 204 is the same, and is in the middle of high reference 222 and low reference 224, indicating that the threshold value is within the signal swing. The comparator then compares the filter output 206 with the high reference 222 and low reference 224 and is used to determine that the threshold value is within the swing range of the signal voltage level 220. To indicate that the threshold value is within the swing range, the output of this determination may be that both outputs signal level below 118 and signal level above 120 are on.

In another operation of the activity detection system according to the present invention, threshold “D” 212 is placed above the input voltage signal 220. The differential gain stages 102 and 104 will then output a voltage level at the digital high level because the threshold input 114 is above the signal 116 at all times. It is important to note that if the threshold level 114 is only slightly above the signal 116, the differential stage 102 and 104 will not properly amplify the signal 116. Therefore, the differential stages 102 and 104 should have enough gain to properly amplify the signal 116, either with adequate gain for each stage or by using additional gain stages. The output from the differential gains stages then reaches the filter. Since the output is the digital high value, the filter output level 214 obtained by the filter is also a digital high. The high reference should be at a level below the digital high, so that the comparator 108 can make the determination that the threshold “D” 212 is above the signal voltage level 220. A similar operation can be performed with a threshold “C” 208 below the signal voltage level 220. If filter output 210 is below the low reference, the comparator 108 can determine that threshold C 208 is below the signal voltage level 220.

The high reference 222, corresponding to high reference 110 in FIG. 1, should be set such that they are in between the filter output 206 when a threshold level is set in the swing range of the input signal and the high level 214 outputted by the filter when a threshold level is set above the swing range of the input signal. The low reference 224, corresponding to low reference 112 in FIG. 1, should be set such that they are in between the filter output 206 when a threshold level is set in the swing range of the input signal and the low level 210 outputted by the filter when a threshold level is set below the swing range of the input signal. The exact position of the references should be set so that the maximum margins for comparing against filter outputs 206, 210 and 214.

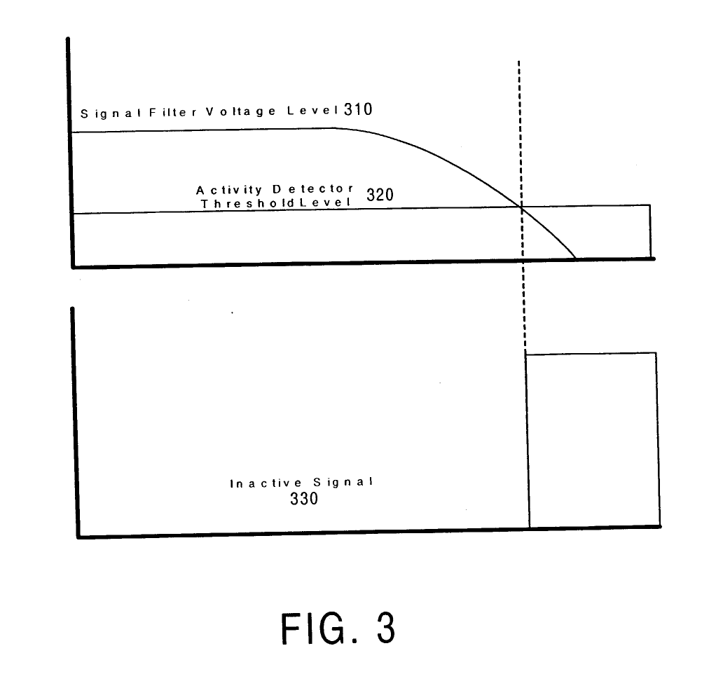

FIG. 3 is a graph of one aspect of operation of the activity detection system according to the present invention. Specifically, FIG. 3 depicts the operation of detecting an signal that has been low for an extended period of time, potentially indicating a failed source device or broken connection. A signal filter voltage level 320 is obtained from a digital signal voltage level. A threshold level 330 is also established. When the threshold is crossed by the filtered level 320, the threshold level 330 is lowered below the normal low level of the signal 310. If the new threshold is crossed, then the signal is inactive. If not, then the signal has been low for an extended period of time. A stuck low indicator signal 340 can be turned on to indicate that the signal voltage level 310 has been low for an extended period of time.

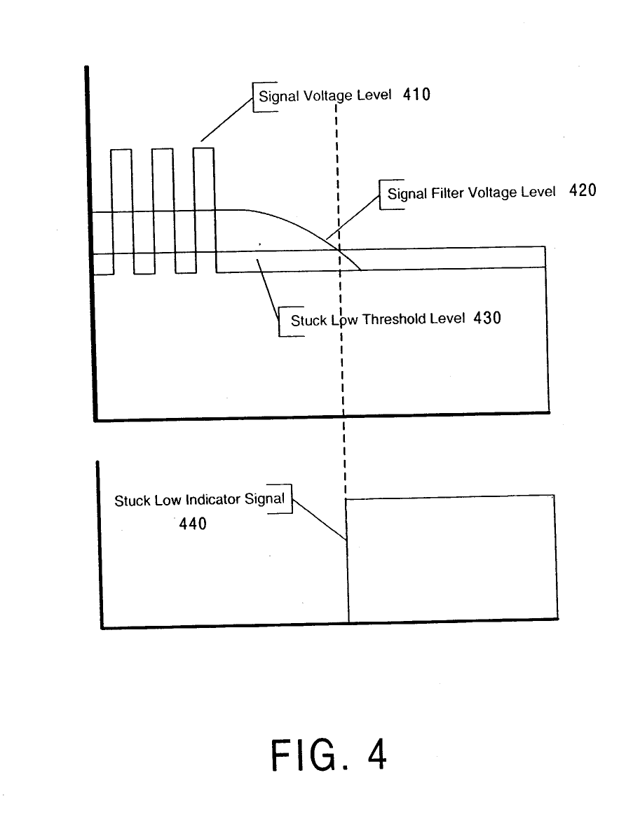

FIG. 4 is a graph of a second aspect of operation of the activity detection system according to the present invention. Specifically, FIG. 4 depicts the operation of detecting an signal that has been on for an extended period of time, potentially indicating that a device is stuck “on”. The operation depicted in FIG. 4 is analogous to the operation depicted in FIG. 3 except that a stuck high indicator signal 440 will turn on when signal filter voltage level 420 exceeds threshold 430, to indicate that the signal voltage level has been high for an extended period of time. Accordingly, the threshold level 430 is close to the high voltage level of the signal voltages level 410.

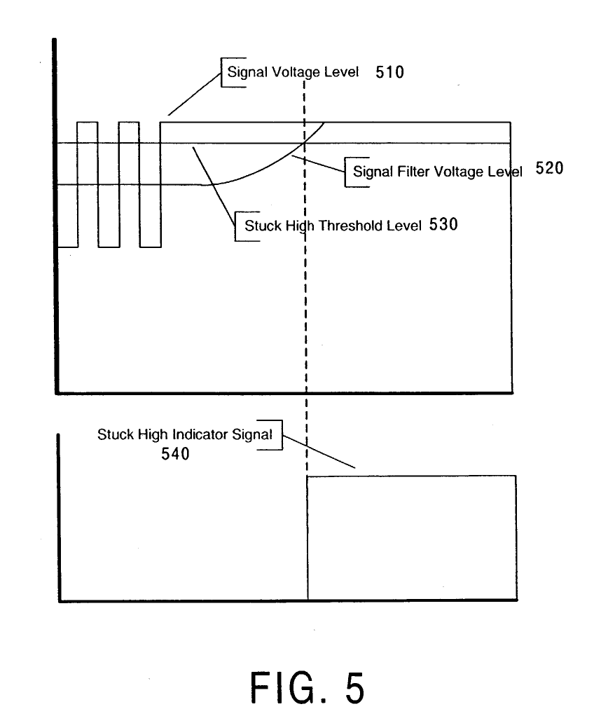

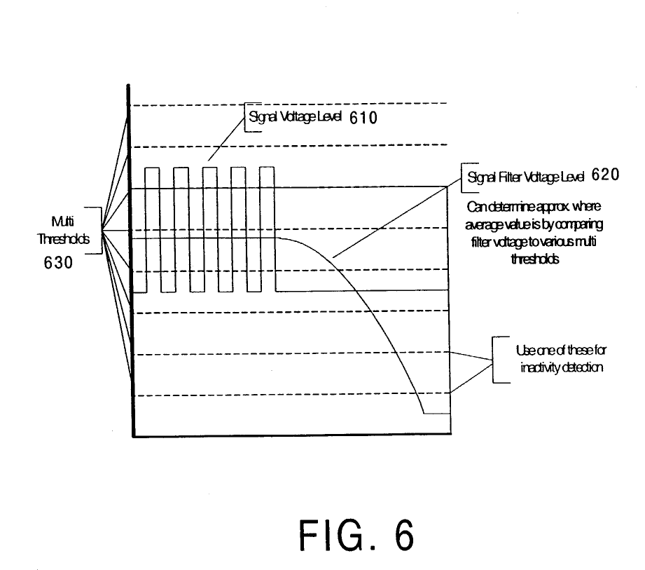

FIG. 5 is a graph of a third aspect of operation of the activity detection system according to the present invention. Specifically, FIG. 5 depicts the operation of detecting the DC averages of a signal using multiple thresholds. In the operation, multiple thresholds 530 are set, and each threshold can trigger an indicator. The thresholds 530 can be set within the swing of signal voltage level 510, or they can be set beyond the high and low voltages. Using multiple thresholds 530 allow a user to tell, with varying degrees of accuracy depending on the granularity of the thresholds, where in the range of possible values of the signal voltage level 510 the DC average of the signal voltage 510 is, and how the DC level changed over time. Advantageously, providing this mode of operation does not require reprogramming an activity detector of the present invention. Moreover, particular thresholds at the higher or lower levels can be used like the activity detector thresholds, to detect if a device or connection is inactive, stuck low or stuck high.

Thus an activity detection system according to the present invention can be used as a multiple use activity detector. The operation of an activity detector is implemented using the activity detection system of the present invention as follows. The threshold level 114 is be set between the middle and the lower bound of the swing range of the signal voltage level 116. When the source device is inactive, the signal voltage level 116 will fall below the threshold level 114 which is similar to the scenario described for threshold “D” 212 in FIG. 2. When the signal voltage level 116 is inactive and falls below the threshold level 114, the differential gain stages 102 and 104 will swing to a digital high value. The filter output for the digital high value will be above the high reference and the signal level below output 118 of the comparator will be on. Then, the output of the comparator 108, such as signal level below 118, is be used to indicate inactivity.

Moreover, the system of the present invention can also be used to track input signal drift, which occurs when a DC offset is introduced to the signal. A high threshold is set for positive DC offset and a low threshold is set for a negative DC offset. When the DC offset is so severe that the entire signal is above or below the threshold, a scenario similar to that described for threshold “D” 212 or threshold “C” 208 will result, and an indication will be made by the outputs of the comparator 108. If a control system is used to change the threshold in regular increments, then activity detection system according to the present invention can be made to perform the operation depicted in FIG. 5, specifically finding the DC average of a signal. For example, when an input signal has a positive DC offset, the threshold level is initially set at level below the signal. Then, the threshold is incremented so that a threshold level is found to be where the next increment takes the threshold into the swing range. This change can be observed by the changes in signal below level 118 and signal above level 120. As the threshold level enters the swing range of the input signal, the filter output from the filter 106 represents the DC average of the input signal, and the threshold level represents the lower bound of the input signal. As the threshold level continues to increment, the higher bound of the input signal is also found.

A similar procedure can be to make the activity detector system according to the present invention to be self-adjusting. As mentioned above, often the input signal may have a DC offset and the voltage levels will drift. If the threshold levels are statically set, then errors will occur. For example, a input signal without an DC offset swings nominally from 2.0V to 2.3V and the inactive threshold is set at 1.9V. But if the input signal includes a DC offset of −0.5V, the signal will swing from 1.5V to 1.8V, and in the operation of the activity detector system will interpret the signal as being inactive. Therefore, it is desirable for the activity detector system to self-adjust according to the drifting input signal by finding the current average input signal level, and the higher and lower bounds of the inputs signal.

The average input signal level can be found by inputting a threshold level that is in the swing range of the input signal and observing the filtered output, where the filtered output represents the average signal level. The higher and lower bounds of the input signal is found by starting the threshold level at some level and finding the threshold level where signal level below 118 and signal level above 120 changes status. For example, the threshold level starts at the lowest level. At that point signal level above 120 is on. The threshold level is then incremented. When the level is reached where both signal level above 118 and signal level below 120 is on to indicate that the threshold level is in the swing range of the input signal, the threshold level at that point represents the lower bound of the input signal. When the threshold level is reached where only signal level below 118 is on, then the threshold level represents the upper bound of the input signal. With these values determined, a threshold level can be set in between the average level and the lower bound for activity detection operation. Another threshold can be set near the lower bound to determine if the signal has been low for an extended period of time, an operation depicted in FIG. 3. Still another threshold can be set near the upper bound to determine if the signal has been on for an extended period of time, an operation depicted in FIG. 4.

Other components can be added to the activity detection system according to the present invention to make the system even more versatile. For example, a status register can be used to store the outputs of the comparator 108. Using a status register, in combination with a control system that can control the threshold voltage level 114, allows an activity detection system according to the present invention to dynamically and automatically change a threshold level to suit the particular applications.

It should be understood that the above description is only representative of illustrative embodiments. For the convenience of the reader, the above description has focused on a representative sample of all possible embodiments, a sample that teaches the principles of the invention. The description has not attempted to exhaustively enumerate all possible variations. That alternate embodiments may not have been presented for a specific portion of the invention, or that further undescribed alternate embodiments may be available for a portion, is not to be considered a disclaimer of those alternate embodiments. One of ordinary skill will appreciate that many of those undescribed embodiments incorporate the same principles of the invention and others are equivalent.

What is claimed is:

1. An activity detection system for use with a signal having a high value and a low value, the system comprising:
a differential amplifier having an input and an output;
a filter, having an input and an output, the input being connected to the output of the differential amplifier; and
a comparator connected to the output of the filter, the comparator being configured to compare the signal to a threshold value and determine if the threshold value is above the signal, below the signal or in between the high and low values of the signal.

2. A multi-level activity detection system comprising:
at least one differential gain stage;
a comparator stage;
a filter stage located between and connected to the at least one differential gain stage and the comparator stage and constructed to provide an average signal to the comparator stage derived from signals passing through the at least one differential gain stage;
a first reference generator to establish a high threshold level signal;
a second reference generator to establish a low threshold level signal;
the comparator being configured to receive the high threshold level signal and the low threshold level signal and output a result indicating the relationship between the average signal and both the high threshold level signal and the low threshold level signal.

3. An activity detection apparatus comprising:
means for providing an averaged signal;
means, coupled top the means for providing, for receiving the averaged signal, comparing the averaged signal with a pair of threshold signals each having different values, and outputting a result indicative of whether an input signal used to derive the average signal is in one of a stuck high state, a stuck low state or an operational state.
